(19) United States
(12) Patent Application Publication
(10) Pub. No.: US 2004/0013948 A1
(43) Pub. Date: Jan. 22, 2004

(54) Chromeless PSM with chrome assistant feature

(75) Inventors: Chin-Lung Lin, Kaohsiung City (TW); Chuen-Huei Yang, Taipei City (TW); Wen-Tien Hung, Taipei City (TW)

Correspondence Address: LOWE, HAUPTMAN, GOPSTEIN & BERNER, LLP, Suite 310, 1700 Diagonal Road, Alexandria, VA, 22314, US

(73) Assignee: UNITED MICROELECTRONICS CORP.

(21) Appl. No.: 10/199,053

(22) Filed: Jul. 22, 2002

(51) Int. Cl. G03F 1/08

(52) U.S. Cl. 430/5

(57) ABSTRACT

The method includes performing phase shift mask correction to the main feature through the wafer. The method utilized an assistant feature such as a mixed of chromeless pattern and chrome pattern to correct the pattern. In one case, the assistant feature with chrome utilized to correct the feature pattern to simplify the CAD manufacturing. On the other hand, the feature pattern with chrome is used to replace the feature pattern with chromeless to correct the pattern with large critical dimensional such that the small chromeless pattern will not be used during the mask manufacturing and the occurring probability of defect will be improved.

### BACKGROUND OF THE INVENTION

1. Field of the Invention

The present invention generally relates to an optical proximity correction method, and more particularly to a chromeless phase shift mask with chrome assistant feature.

2. Description of the Prior Art

In lithography, exposure energy, such as ultraviolet light, is passed through a mask (or reticle) and onto a target such as a silicon wafer. The reticle typically may contain opaque and transparent regions formed in a predetermined pattern. The exposure energy exposes the reticle pattern on a layer of resist formed on the target. The resist is then developed for removing either the exposed portions of resist for a positive resist or the unexposed portions of resist for a negative resist. This forms a resist mask. A mask typically may comprise a transparent plate such as fused silica having opaque (chrome) elements on the plate used to define a pattern. A radiation source illuminates the mask according to well-known methods. The radiation transmitted through the mask and exposure tool projection optics forms a diffraction limited latent image of the mask features on the photoresist. The resist mask can be used in subsequent fabrication processes. In semiconductor manufacturing, such a resist mask can be used in deposition, etching, or ion implantation processes, to form integrated circuits having very small features.

As semiconductor manufacturing advances to ultra-large scale integration (ULSI), the devices on semiconductor wafers shrink to sub-micron dimension and the circuit density increases to several million transistors per die. In order to accomplish this high device packing density, smaller and smaller feature sizes are required. This may include the width and spacing of interconnecting lines and the surface geometry such as corners and edges, of various features.

Because of increased semiconductor device complexity that results in increased pattern complexity, and increased pattern packing density on the mask, distance between any two opaque areas has decreased. By decreasing the distances between the opaque areas, small apertures are formed. which diffract the light that passes through the apertures. The diffracted light results in effects that tend to spread or to bend the light as it passes so that the space between the two opaque areas is not resolved, therefore, making diffraction a severe limiting factor for optical photolithography.

A conventional method of dealing with diffraction effects in optical photolithography is achieved by using a phase shift mask. Generally, with light being thought of as a wave, phase shifting is a change in timing of a shift in waveform of a regular sinusoidal pattern of light waves that propagate through a transparent material.

Typically, phase-shifting is achieved by passing light through areas of a transparent material of either differing thickness or through materials with different refractive indexes, or both, thereby changing the phase or the periodic pattern of the light wave. Phase shift masks reduce diffraction effects by combining both diffracted light and phase shifted diffracted light so that constructive and destructive interference takes place favorably. On the average, a minimum width of a pattern resolved by using a phase shifting mask is about half the width of a pattern resolved by using an ordinary mask.

In general, these phase shift structures are constructed on reticles (or masks) having three distinct layers of material. An opaque layer is patterned to form light blocking areas that allow none of the exposure light to pass through. A transparent layer, typically the substrate, is patterned with light transmissive areas, which allow close to 100% of the exposure light to pass through. A phase shift layer is patterned with phase shift areas, which allow close to 100% of the exposure light to pass through but phase shifted by 180.degree. (π, pi.) The transmissive and phase shifting areas are situated such that exposure light diffracted through each area is canceled out in a darkened area therebetween. This creates the pattern of dark and bright areas, which can be used to clearly delineate features. These features are typically defined by the opaque layer (i.e., opaque features) or by openings in the opaque layer (i.e., clear features.)

For semiconductor manufacture, alternating aperture phase shift reticles may typically be used where there are a number of pairs of closely packed opaque features. However, in situations where a feature is too far away from an adjacent feature to provide phase shifting, sub-resolution phase shift structures typically may be employed. Sub-resolution phase shift structures typically may be used for isolated features such as contact holes and line openings, wherein the phase shift structures may include assist-slots or outrigger structures on the sides of a feature. Sub-resolution phase shift structures are below the resolution limit of the lithographic system and therefore do not print on the target.

Referring to FIG. 1A, which shows an original mask pattern 100. After the step of exposure, the pattern of photoresist is substantially the same as the pattern shown in FIG. 1B. In order to obtain better pattern transfer, assistant features are generally added to form an optical proximity pattern as shown in FIG. 1B. The assistant features herein include assistant features 102, 104, 106, 108, 110, and 112. These optical proximity correction patterns provide a substantially similar transfer pattern of the original pattern after transferring process. However, the sizes of the assistant features are fairly small; as a result, the assistant features are hard to fabricate and suffer from the difficulties in mask inspection.

The conventional optical proximity correction method to the pattern with assistant feature is that to compensate the difference of the critical dimensional between the dense-pattern and the iso-pattern. Furthermore, in order to prevent the assistant feature being exposure during the exposure process, the profile of the assistant feature should be dotted line. Moreover, for the large pattern shape such as T-shaped pattern with chrome 200 is shown in FIG. 2A. The conventional correction method to the large pattern shaped 200 is utilized assistant features such as chromreless phase shifted mask 202, 204, 206, 208, 210, and 212 to divide the T-shaped pattern into a plurality of feature patterns, wherein the divided plurality of feature patterns is approximately the original T-shaped pattern 200. The drawback of the aforementioned is that the number of the divided assistant features cannot be determined. If many assistant features are utilized due to the distance between the number assistant features is small such that the resolution is decreased after pattern being exposure. On the other hand, the number of the assistant feature cannot be determined, and the pattern inspection will be increased and the file size will be increased. Therefore, according to abovementioned, the conventional feature pattern utilized the chromeless PSM to correct the feature pattern that the duty ratio between the assistant features should be considered. Furthermore, the configuration for the chromeless patterns over the large pattern is an important issue. The assistant feature is used to correct the feature pattern nor the pattern is divided into plurality of the chromeless pattern, the difficult of the CAD (computer-aided design), and the mask manufacturing is increased.

### SUMMARY OF THE INVENTION

It is another object of this invention to provide an optical proximity correction method for correcting the pattern feature.

It is a further object of this invention to improve the difference between the dense pattern and the iso-pattern.

It is still another object of this invention to utilize the chrome assistant feature as the assistant feature to correct the pattern during the photolithography process.

It is yet another object of this invention to utilize the chrome assistant feature as the feature pattern with a higher critical dimensional to correct the pattern during the photolithography process.

According to abovementioned objects, the present invention provides a method for phase shift mask with assistant optical proximity correction, in which the mask comprises a transparent plate and a main feature region. The method includes performing phase shift mask correction to the main feature through the wafer. The method utilized an assistant feature such as a mixed of chromeless and chrome pattern to correct the pattern. In one case, the assistant feature with chrome utilized to correct the feature pattern to simplify the CAD manufacturing. On the other hand, the feature pattern with chrome is used to replace the feature pattern with chromeless such that the small chromeless pattern will not be used during the mask manufacturing and the occurring probability of defect will be improved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1B are schematic vertical views showing the steps for carrying out a conventional chromeless assistant feature to a pattern in accordance with the prior art;

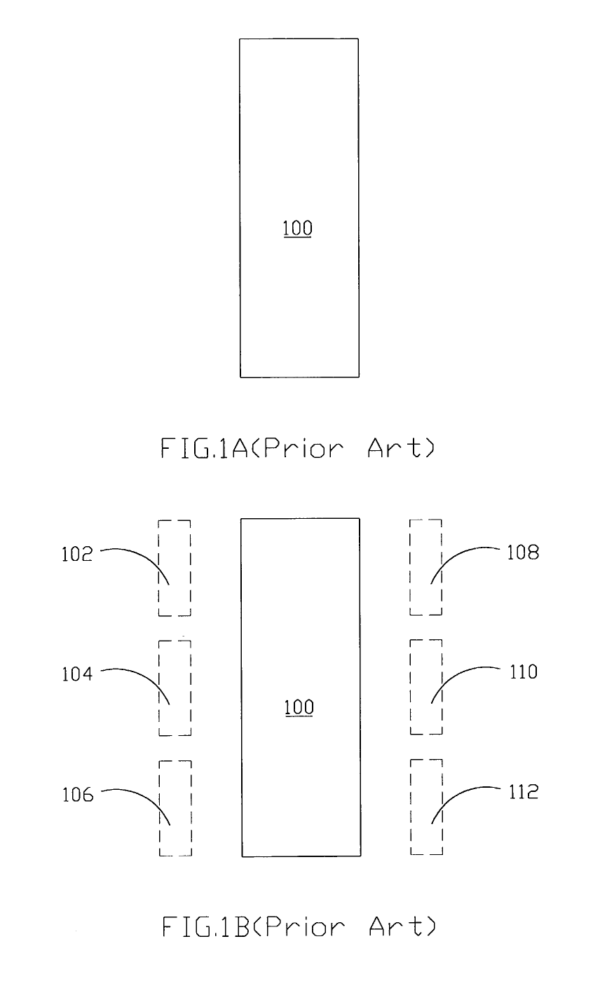

FIGS. 2A to 2B are schematic vertical views showing the steps for carrying out a conventional chrome assistant feature to a pattern with large critical dimensional in accordance with the prior art;

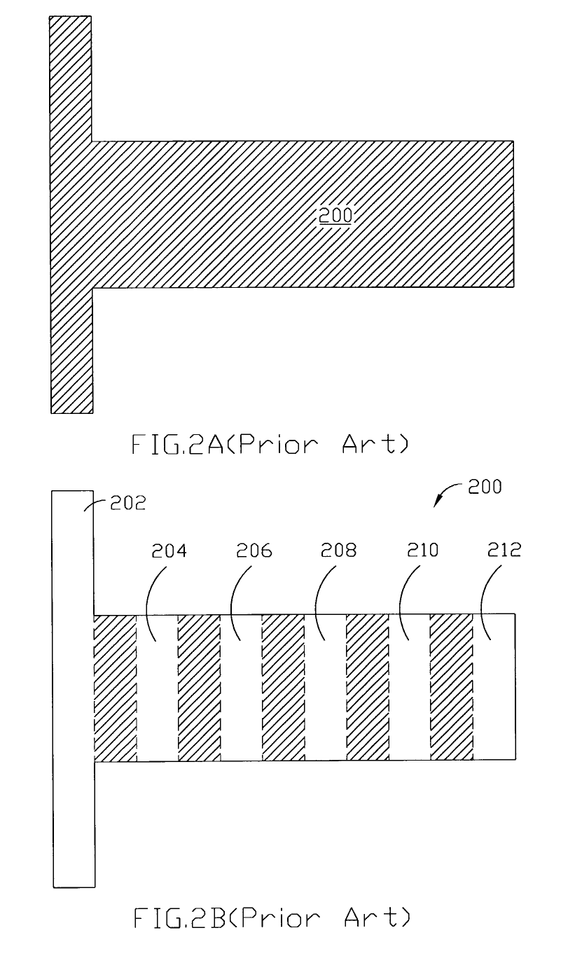

FIGS. 3A to 3B are schematic vertical views showing an assistant feature with chrome feature pattern to correct the pattern in accordance with a method disclosed herein; and

FIG. 4 is schematic vertical views showing an assistant feature with chrome feature pattern to correct the pattern with large critical dimensional in accordance with a method disclosed herein.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

The photolithography technique include the photosensitive material is first coated on the wafer. Then, the light source is projected to the photosensitive material through the mask, which is mainly composed of glass. The light beam through the mask has the same pattern as the mask so that the mask pattern can be transferred to the photosensitive material on the wafer. The photosensitive material can be photoresist. Then, after exposure or/and development, equal or complementary pattern on the mask can be transferred to the photosensitive material. If the photosensitive material is positive photoresist, it will obtain a pattern as same as the mask. On the other hand, of the photosensitive material is negative photoresist, it will obtain a complementary pattern as the mask.

The present invention provided a mixed of chromeless and a chrome patterns for correcting the pattern to diminish the occurrence probability of the defect and obtain a simple mask manufacturing process.

The approach of the present invention utilized a mixed of a chromeless and the chrome pattern assistant feature to correct the pattern to obtain the better re-solution. Correcting the feature pattern with assistant feature can achieve better resolution of the pattern and reduce the file size; herein the feature pattern can be a polygon feature pattern. In addition, the mask writing time is also improved since the original feature pattern is divided into a few small feature patterns, and the pattern inspection is also simplified.

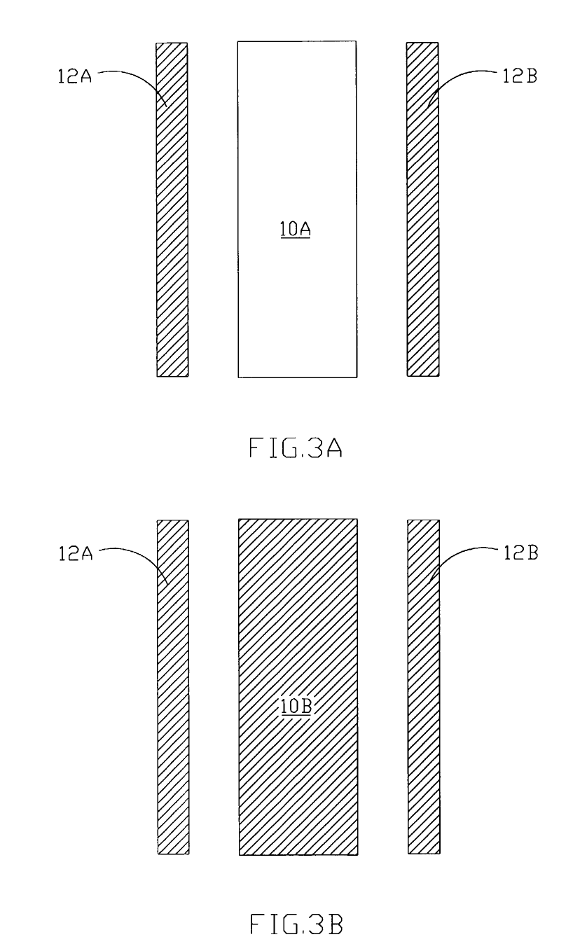

Traditional chromeless phase shift mask cannot determined the number of duty ratio that should be added into the dotted line of the assistant feature such that the feature pattern cannot obtained the better resolution when the light source illuminated through the reticle. In order to improve the resolution of the pattern, the present invention provided a mixed mode of the chromeless and the chrome pattern to correct the pattern. Referring to FIG. 3A is schematic vertical views showing polygon feature patterns such as a quadrilateral feature pattern with chromeless 10A. One of the embodiments of the present invention provided a transparent plate formed by quartz. Then, the main feature on the reticle is a transparent pattern coated on the reticle, and a least two assistant feature 12A, 12B with chrome on the reticle adjacent to the main feature 10A. Then, the transparent pattern is imaged onto a photoresist layer coated on a wafer in photolithography, and the beneath layer is etched with the photoresist stripped to form integrated circuit on the wafer. The FIG. 3B is showing an alternative embodiment of the present invention, the present invention provided an opaque plate formed by quartz. Then, the main feature 10B on the reticle is an opaque pattern coated on the reticle by chrome, and at least two assistant features 12A, 12B with chrome adjacent to the main feature 10B. Therefore, due to the mixed mode of chrome and chromeless phase shift mask are used to replace the conventional chromeless pattern or chrome assistant feature pattern, such that the number of duty ratio should not be added into the dotted line of the feature pattern and the complexity of the pattern rule can be simplified.

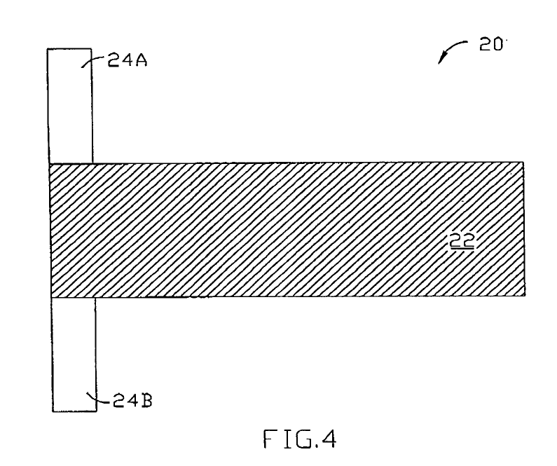

Furthermore, the main feature pattern is a large feature pattern with large critical dimensional 20 such as T-shaped, L-shaped, or the like as shown in FIG. 4. The large feature pattern 20 has a drawback such as process small chromeless pattern, the long mask writing time, the mask inspection time will be increased and the file size will also be increased during the mask pattern manufacturing. Therefore, in order to solve the aforementioned drawbacks, the present invention provided alternative embodiment is that a mixed mode of chrome feature and chromeless feature pattern is utilized to correct the large feature pattern with large critical dimensional. In the present invention, the original pattern 20 is divided into a plurality of blocks. The chrome feature pattern 22 replaced the small pattern with chromeless to correct the feature pattern 20 that coated on the large block of the transparent plate, and chromeless pattern 24A, 24B coated on the other pluralities of small block of the transparent plate to replace the conventional chromeless with small process to correct the feature pattern such that the duty ratio between the each chromeless feature should not be added and the after exposing steps, the resolution is better than the conventional chromeless feature pattern. Therefore, after expousing, the resolution can be improved, the defect occurring probability will be decreased, and the mask manufacturing process can be simplified.

Although specific embodiments have been illustrated and described, it will be obvious to those skilled in the art that various modifications may be made without departing from what is intended to be limited solely by the appended claims.

What is claimed is:

1. A phase shift mask for photolithography process used in fabricating integrated circuits, said mask comprising:
a first transparent plate;
a first opaque film, formed on said first transparent plate, having a first pattern defining a main feature region, said first pattern being then imaged onto a photoresist layer coated on a wafer for the integrated circuits;
at least one phase shift region, formed on said first transparent plate;
at least two second transparent plates located adjacent to said first transparent plate; and
at least two second opaque films, formed on said at least two second transparent plates, having at least two feature patterns, wherein said at least two feature patterns are located alongside and separated form said first pattern of said first opaque film, and wherein said at least two feature patterns are then imaged onto said wafer with said phase shift region and said first pattern.

2. The mask according to claim 1, wherein said transparent plate comprises quartz.

3. The mask according to claim 1, wherein said first opaque film comprises chrome film.

4. The mask according to claim 1, wherein said at lease two second opaque films comprises chrome film.

5. A chromeless phase shift mask with chrome assistant feature, said chromeless phase shift mask comprising:
a first transparent plate;
a first film, formed on said first transparent plate, having a first pattern defining a main feature region, said pattern being then imaged onto a photoresist layer coated on a wafer for the integrated circuits;
at least one phase shift region, formed on said first transparent plate;
at least two second transparent plates located adjacent to said first transparent plate; and
at least two opaque films, formed on said at least two second transparent plate, having at least two feature patterns, wherein said at least two feature patterns are located alongside and separated form said first pattern of said first film, and wherein said at least two feature patterns are then imaged onto said wafer with said phase shift region and said first pattern.

6. The mask according to claim 5, wherein said first transparent plate comprises quartz.

7. The mask according to claim 5, wherein said first film comprises chrome.

8. The mask according to claim 5, wherein said first film comprises chromeless.

9. The mask according to claim 5, wherein said at lease two second opaque films comprises chrome.

10. A chromeless phase shift mask with chrome assistant feature, said chromeless phase shift mask comprising:
a transparent plate;
a film, formed on a potion of said transparent plate such that said transparent plate is divided into a plurality of blocks, wherein said film having a pattern defining a main feature region, said pattern being then imaged onto a photoresist layer coated on a wafer for the integrated circuits; and
at least one phase shift region, formed on said transparent plate.

11. The mask according to claim 10, wherein said transparent plate is a polygon shaped plate.

12. The mask according to claim 11, wherein said transparent plate comprises quartz.

13. The mask according to claim 11, wherein chrome located on said large of portion of said transparent plate.

14. The mask according to claim 11, wherein said film comprises chromeless film formed on plurality of said blocks of said transparent plate, wherein the area of said plurality of said blocks with chromeless film is smaller than said portion of said transparent plate with said chrome film.
